(19) United States
(12) Patent Application Publication
(10) Pub. No.: US 2019/0078231 A1
(43) Pub. Date: Mar. 14, 2019

(54) HYBRID CRUCIBLE ASSEMBLY FOR CZOCHRALSKI CRYSTAL GROWTH

(71) Applicant: Corner Star Limited, Kowloon (HK)

(72) Inventors: Arash Mehdizadeh Dehkordi, O'Fallon, MO (US); Joseph Conrad Holzer, St. Peters, MO (US)

(21) Appl. No.: 16/125,076

(22) Filed: Sep. 7, 2018

Related U.S. Application Data
(60) Provisional application No. 62/555,900, filed on Sep. 8, 2017.

(51) Int. Cl. C30B 15/12; C30B 15/30; C30B 29/06

(52) U.S. Cl. CPC C30B 15/12; C30B 15/002; C30B 29/06; C30B 15/30

(57) ABSTRACT

A crucible assembly for growing a crystal ingot using a Czochralski process includes an outer crucible and an inner crucible. The inner crucible is disposed within the outer crucible and has a channel configured for fluid communication between the outer crucible and the inner crucible. The inner crucible is an arc-fused crucible and the outer crucible is a cast crucible.

### CROSS-REFERENCE TO RELATED APPLICATIONS

This application claims priority to U.S. Provisional Patent Application Ser. No. 62/555,900, filed on Sep. 8, 2017, the disclosure of which is hereby incorporated by reference in its entirety.

### FIELD

This disclosure relates generally to systems and methods for producing ingots of solar-grade or semiconductor material and, more particularly, to crucible assemblies including two types of crucibles for use in such systems and methods.

### BACKGROUND

Crystalline silicon solar cells currently contribute the majority of the total supply of the photovoltaic (PV) modules. In the standard Czochralski (CZ) method, polycrystalline silicon is first melted in a crucible, such as a quartz crucible, to form a silicon melt. A seed crystal of predetermined orientation is then lowered into contact with the melt and is slowly withdrawn. By controlling the temperature, silicon melt at the seed-melt interface solidifies onto the seed crystal with the same orientation as that of the seed. The seed is then slowly raised from the melt to form a growing crystal ingot. In the conventional CZ process, called batch CZ (BCZ), the entire amount of charge material needed for growing a silicon ingot is melted at the beginning of the process, a crystal is pulled from a single crucible charge to substantially deplete the crucible, and the quartz crucible is then discarded.

Another method to economically replenish a quartz crucible for multiple pulls in one furnace cycle is continuous CZ (CCZ). In CCZ, the solid or liquid feedstock is continuously or periodically added to the melt as the crystal is grown and therefore maintains the melt at a constant volume. In addition to spreading the crucible cost across several ingots, the CCZ method provides superior crystal uniformity along the growth direction. Moreover, by maintaining the melt volume constant, steady thermal and melt flow condition can be achieved, which provides optimal growth conditions at the crystallization front. Large diameter crucible assemblies needed to grow large diameter ingots using CCZ method possess the second highest cost factor next to polysilicon material and their lifespan dictates the length of a furnace cycle.

Known crucibles of sufficient diameter for use in multiple crucible assemblies are expensive, suffer from limited design flexibility, and have limited crucible lifetimes. Thus, there exists a need for a multiple crucible assembly which is inexpensive, has improved design flexibility and improved crucible lifetime, e.g., to extend the length of a furnace cycle.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

In one aspect, a crucible assembly for growing a crystal ingot using a Czochralski process includes an outer crucible and an inner crucible. The inner crucible is disposed within the outer crucible and has a channel configured for fluid communication between the outer crucible and the inner crucible. The inner crucible is an arc-fused crucible and the outer crucible is a cast crucible.

In another aspect, a method of growing a single crystal ingot by a Czochralski process includes melting semiconductor or solar-grade material in a crucible assembly to form a melt. The crucible assembly includes an inner, arc-fused crucible disposed within an outer, cast crucible. The method further includes pulling a single crystal of semiconductor or solar-grade material from the melt within the inner crucible.

In a further aspect, a method of manufacturing a crucible assembly having an inner crucible disposed within an outer crucible includes forming a first crucible using an arc-fusion process and forming a second crucible using a casting process. The second crucible has an inner diameter larger than an outer diameter of the first crucible. The method further includes positioning the first crucible within the second crucible.

In a further aspect, a method of assembling a crucible assembly includes providing an arc-fused crucible and providing a cast crucible. The cast crucible has a larger diameter than the arc-fused crucible. The method further includes positioning the arc-fused crucible within the cast crucible and fixing the arc-fused crucible to the cast crucible.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1 is a sectional view of a crucible assembly including an inner crucible and an outer crucible.

FIG. 2 is a plan view of the crucible assembly shown in FIG. 1.

FIG. 3 is a detailed sectional view of the crucible assembly shown in FIG. 1.

FIG. 4 is a sectional view of the crucible assembly shown in FIG. 1 including molten material contained within the crucible assembly.

FIG. 5 is a flow chart illustrating one suitable method for making a crucible for use in the crucible assembly shown in FIG. 1.

FIG. 6 is a flow chart illustrating one suitable method for making the crucible assembly shown in FIG. 1.

FIG. 7 is a flow chart illustrating one suitable method of growing a crystal ingot using the crucible assembly shown in FIG. 1.

FIG. 8 is a sectional view of an alternative crucible assembly including an inner crucible, an intermediate crucible, and an outer crucible.

FIG. 9 is a plan view of the crucible assembly shown in FIG. 8.

Corresponding reference characters indicate corresponding parts throughout the several views of the drawings.

### DETAILED DESCRIPTION

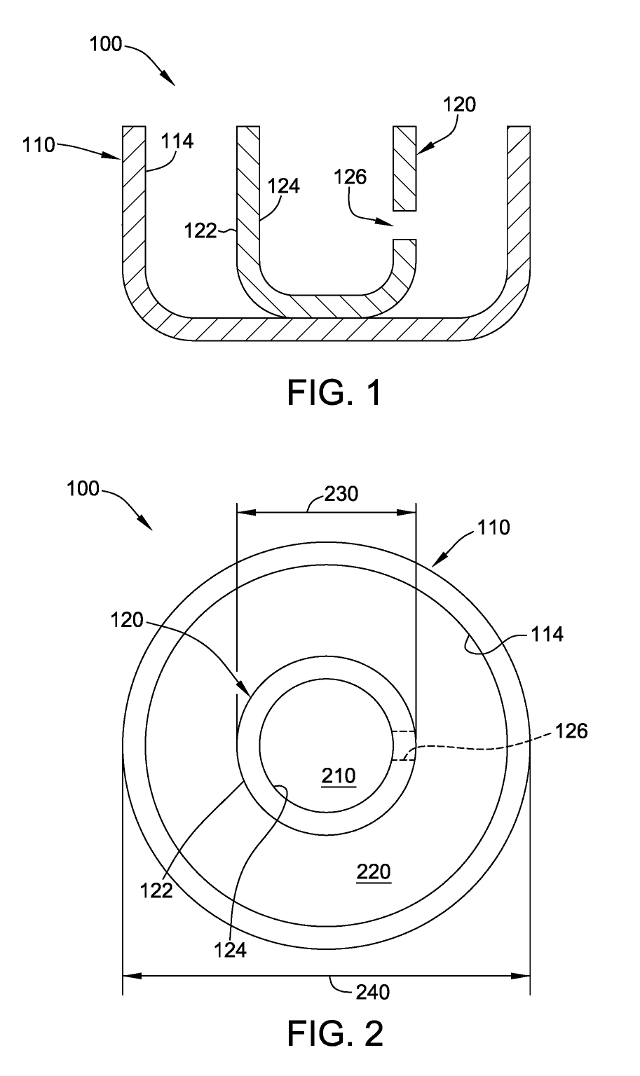

Referring now to FIG. 1, a crucible assembly 100 of one example embodiment includes a plurality of crucibles. The crucible assembly 100 includes an outer crucible 110 and an inner crucible 120. The crucible assembly 100 includes crucibles of two different types and made by different processes. In comparison to a crucible assembly having only a single type of crucible, this provides for a reduced overall cost of crucible assembly 100, increased design flexibility, and increased crucible lifetime.

Inner crucible 120 is an arc-fused crucible formed by an arc-fusion process. The process generally includes fusing a precursor material (e.g., high purity quartz sand) with an electrical arc. In one embodiment, the inner crucible 120 is formed by pouring high purity quartz sand into a rotating mold, and then fusing from the inside out using an arc generated by two or more graphite electrodes. High purity quartz sand is defined as sand which contains no more than 30 parts per million by weight of impurities. The industry standard for high purity quartz is defined by a product marketed as IOTA mined by Unimin Corporation at Spruce Pine, N.C., US, which serves as the high-purity benchmark for the high-purity quartz market. In this embodiment, the high purity quartz sand has a total impurity level not exceeding 20 parts per million by weight. The mold may include vacuum holes through which air trapped between the sand particles, as well as the gaseous species generated during the fusion process, are removed in order to avoid the formation of bubbles in the final as-fused crucible. The resulting arc-fused crucible is substantially transparent or semi-transparent, depending on the bubble density, at room temperature.

In batch or recharge Czochralski processes, ultra-high purity natural sand or synthetic quartz, e.g., SiO₂, may be used for an interior wall of the inner crucible, which is in contact with molten silicon within the growth zone, whereas the rest of the crucible wall is made of lower purity sand. This configuration may also be used for continuous Czochralski processes. Ultra-high purity natural sand has a higher purity than high purity natural sand, such as no more than 10 parts per million by weight. Synthetic quartz has a higher purity than ultra-high purity natural sand, such as no more than 5 parts per million by weight, or no more than 1 part per million by weight.

In alternative embodiments, both interior and exterior walls of the inner crucible may be formed from ultra-high purity natural sand or synthetic quartz. In yet further alternative embodiments, the entire inner crucible is made from a single material or predominantly a single material. For example, the inner crucible may be made entirely of ultra-high purity natural sand or synthetic quartz having less than 20 parts per million impurities by weight.

In the example crucible assembly 100, the inner crucible 120 has an inner wall 124 and an outer wall 122. Inner wall 124 is made from ultra-high purity natural sand or synthetic quartz. The remainder of the crucible wall including outer wall 122 is made from lower purity materials. Inner crucible 120 has at least one channel 126 defined therein that extends radially through the inner crucible 120. Channel 126 is configured to allow melt material to flow from outside the inner crucible 120 (e.g., from between outer crucible 110 and inner crucible 120) to within a cavity defined by the inner crucible 120. Channel 126 is an opening within the wall of inner crucible 120. The opening of channel 126 extends through outer wall 122 and inner wall 124. During operation, molten material flows from a cavity defined by outer crucible 110 into a cavity defined by inner crucible 120 through channel 126. For example, as a crystal ingot is pulled from within inner crucible 120, molten material flows from the cavity defined by outer crucible 110 into the cavity defined by inner crucible 120 to replenish the material removed as the crystal ingot is pulled. Additional material can be added to outer crucible 110 to replenish material which has passed through channel 126 into inner crucible 120. In some embodiments, additional material added to outer crucible 110 is added opposite channel 126.

In some embodiments, inner crucible 120 has a single channel 126. In alternative embodiments, inner crucible 120 includes a plurality of channels 126. For example, inner crucible 120 may have two, four, or any other number of channels 126.

Inner crucible 120 is disposed within outer crucible 110. In the illustrated embodiment, inner crucible 120 is concentric with (i.e., centered within) outer crucible 110. In some embodiments, inner crucible 120 is fixed (i.e., non-movably attached) to outer crucible 110. For example, inner crucible 120 is bonded to outer crucible 110 by using silica nanoparticles, which bind inner crucible 120 to outer crucible 110.

Outer crucible 110 is suitably a slip cast crucible, but may be another type of cast crucible. Cast crucibles are crucibles formed by a process other than arc-fusion, such as a casting process. Casting processes suitable for forming cast crucibles generally include pouring a liquid or semi-liquid compound into a mold, and allowing the compound to solidify by removing moisture from the compound. The compounds used to form cast crucibles may include, for example and without limitation, an aqueous slurry of ceramic powder, such as silica powder. Suitable casting processes for forming cast crucibles include, for example and without limitation, slip casting and gel casting. Slip casting includes the use of aqueous slurry of ceramic powder, e.g., silica, known as slip. The ceramic powder may be mixed with dispersing agents, binders, water, and/or other components. The slip and/or slip mixture, e.g., slurry, is poured into a mold. For example, the mold is suitably made of plaster of Paris, e.g., CaSO₄:2H₂O. The water from the slurry begins to move out by capillary action (or with the help of vacuum drying), and a mass builds along the mold wall. When the desired thickness of the dried mass is reached, the rest of the slurry is poured out of the mold. The green ceramic is then removed from the mold, dried, and fired. The firing process includes sintering, or fusing in the case of silica, at high temperature. The end product is opaque at room temperature but can be transparent depending on the sintering condition and temperature.

Outer crucible 110 formed using the slip casting process, or other casting process, can have a density of greater than ninety to ninety five percent of the maximum theoretical density for silica slip cast crucibles. Outer crucible 110 formed by the slip cast process and made of silica possesses similar thermal shock resistance properties to that of amorphous arc-fused crucibles. In embodiments where outer crucible 110 is made of silica, outer crucible 110 includes a silica wall.

Cast crucibles of this embodiment are opaque at room temperature, in contrast to arc-fused crucibles that are typically transparent or semi-transparent. Note that cast crucibles of other embodiments may be transparent, e.g., depending on sintering conditions used in firing the cast crucible.

In comparison to arc-fused crucibles, cast crucibles typically require additional input power and time to melt material contained therein, due to reduced infrared transmission through the opaque cast crucible in comparison to transparent or semi-transparent arc-fused crucibles. However, the decrease in infrared transmission of cast crucibles may result in less radiative heat loss from the melt after the melt down in comparison to arc-fused crucibles. As a result, a cast crucible might not vary in overall power consumption throughout a run compared to arc-fused crucibles. Cast crucibles have a dissolution rate lower than the dissolution rate of arc-fused crucibles. Additionally, slip cast crucibles typically have higher levels of impurities in comparison to arc-fused crucibles. Slip cast crucibles include a wall of substantially uniform material. This is in contrast to an arc-fused crucible which may include a wall having both an interior wall portion of at least one of ultra-high purity natural sand or synthetic quartz and an outer wall portion of lower purity sand or quartz than the interior wall.

Outer crucible 110 formed using the slip casting process, or other casting process, provides greater design flexibility over that of arc-fused crucibles and provides significant cost reductions as compared to arc-fused crucibles. The use of a mold and slurry in the slip casting process allows for less costly design changes in comparison to the arc-fusion process. The size and/or shape of outer crucible 110 may be changed using the slip casting process with reduced capital expenditure compared to arc-fusion as a result of the flexibility and lower cost of the slip cast mold and slurry in comparison to the equipment used in the arc-fusion process. The high cost of capital equipment used in the arc-fusion manufacturing process as well as the cost of high-purity quartz sand, e.g., having less than 30 parts per million of impurities, make the arc-fused crucibles used in Czochralski crystal growth processes expensive consumables. As the size of the crucible made by the arc-fusion process increases, the cost likewise increases. Therefore, using a slip cast crucible, or other cast crucible, as outer crucible 110 in crucible assembly 100 reduces cost while providing increased flexibility of the size and geometry of outer crucible 110.

Outer crucible 110, in general, includes greater amounts of impurities than a crucible made using the arc-fusion process. In other words, the inner crucible 120 is formed from higher purity materials (e.g., quartz sand) than the outer crucible 110. This is a result of the slip cast process, or other casting process, used to make the crucible. In alternative embodiments, outer crucible 110, formed by a slip cast process or other casting process, has a low amount of impurities. For example, outer crucible 110 has 20 parts per million, by weight, or less of impurities. Impurities, such as aluminum, have a significant impact on low-injection minority carrier lifetime in crystals and lower the efficiency of solar cells made from the crystals. A high purity cast outer crucible 110 reduces impurities and results in more efficient solar cells.

In some embodiments, cast outer crucible 110 and/or other cast crucibles in crucible assembly 100 have an impurity content greater than 50 parts per million by weight (ppmw), greater than 100 ppmw, greater than 200 ppmw, between 50 ppmw and 1,000 ppmw, between 50 ppmw and 500 ppmw, between 100 ppmw and 1,000 ppmw, between 100 ppmw and 500 ppmw, between 100 ppmw and 400 ppmw, between 200 ppmw and 300 ppmw, greater than 1000 ppmw, or other impurity content greater than that of an arc-fused crucible (e.g., having an impurity content of less than 20 ppmw). Examples of impurities that are measured or accounted for in the total impurity content of a crucible include, for example, Al, B, Ba, Ca, Cr, Cu, Fe, K, Li, Mg, Mn, Na, Ni, P, Ti, Zn, and Zr. For example, a cast crucible may have a total impurity content of less than 230 ppmw with the following specific impurity contents: 100 ppmw Al, 1 ppmw B, 10 ppmw Ba, 20 ppmw Ca, less than 1 ppmw Cu, 20 ppmw Fe, 15 ppmw K, 10 ppmw Li, 9 ppmw Mg, 23 ppmw Mn, 10 ppmw Na, 10 ppmw Ti, and less than 1 ppmw Zr.

In comparison, arc-fused crucibles of the present disclosure may have an impurity content less than that of slip crucibles, such as less than 50 ppmw, less than 30 ppmw, less than 20 ppmw, less than 15 ppmw, less than 10 ppmw, less than 1 ppmw, less than 0.5 ppmw, between 0.01 ppmw and 50 ppmw, between 0.01 ppmw and 30 ppmw, between 0.01 ppmw and 20 ppmw, between 5 ppmw and 50 ppmw, between 10 ppmw and 30 ppmw, or other impurity content less than that of a slip cast crucible. For example, an arc-fused crucible may have a total impurity content of less than 13 ppmw with the following specific impurity contents: 8 ppmw Al, less than 0.05 ppmw B, 0.7 ppmw Ca, 0.006 ppmw Cr, 0.002 ppmw Cu, 0.3 ppmw Fe, 0.4 ppmw K, 0.2 ppmw Li, 0.06 ppmw Mg, 0.013 ppmw Mn, 1 ppmw Na, 0.002 ppmw Ni, less than 0.05 ppmw P, 1.3 ppmw T, and 0.01 ppmw Zn. In other embodiments, cast crucibles and/or arc-fused crucibles have various total impurity contents, various specific impurity contents, and/or other types of impurities.

Outer crucible 110 formed using a slip casting process, or other casting process, has a lower dissolution rate in comparison to arc-fused crucibles. In operation, a dissolution reaction occurs between molten silicon within outer crucible 110 and inner wall 114 of outer crucible 110 at the melt free surface. The molten silicon gradually dissolves inner wall 114 forming a groove at the melt free surface which increases in depth as the process progresses. This reaction limits the lifetime of crucible assembly 100. In a multiple crucible assembly, outer crucible 110 lifespan limits the lifespan of the entire system because, for example, the outer crucible 110 is exposed to one or more heating elements and additional material added to the melt. Use of a cast outer crucible 110, e.g., made using a slip casting or gel casting process, increases the lifetime of crucible assembly 100 in comparison to use of an arc-fused crucible for outer crucible 110 as cast crucibles have a lower dissolution rate than arc-fused crucibles.

In alternative embodiments, outer crucible 110 is formed by a non-casting process. For example, outer crucible 110 is formed using an arc-fusion process.

Referring now to FIG. 2, a plan view of the crucible assembly 100 shown in FIG. 1 is illustrated. Outer crucible 110 and inner crucible 120 are circular. Inner crucible 120 is nested within outer crucible 110. For example, inner crucible 120 is centered within outer crucible 110. Outer crucible 110 has a larger diameter 240 than the diameter 230 of inner crucible 120. In some embodiments, outer crucible 110 has an outer diameter 240 of at least twenty inches, less than forty inches, between twenty four inches and thirty two inches, between twenty eight inches and thirty four inches, or between thirty inches and thirty six inches. Inner crucible 120 has an outer diameter 230 of at least eighteen inches, less than thirty inches, between eighteen inches and twenty two inches, between twenty two inches and twenty six inches, or between twenty six inches and thirty inches.

In alternative embodiments, inner crucible 120 and/or outer crucible 110 have other configurations. Inner crucible 120 and/or outer crucible 110 may have different diameters in some embodiments. For example, inner crucible 120 may have a diameter of ten inches or less, or alternatively be greater than twenty four inches. Outer crucible 110 may have a diameter less than twenty two inches, or alternatively greater than forty inches. Outer crucible 110 may be cast using a casting process other than slip casting. For example, outer crucible 110 may be cast using a gel casting process or other casting process.

Outer crucible 110 and inner crucible 120 define a non-growth zone 220. The crystal ingot generated by the Czochralski process is not pulled from non-growth zone 220. Non-growth zone 220 extends from inner wall 114 of outer crucible 110 to outer wall 122 of inner crucible 120. Inner crucible 120 defines growth zone 210. The crystal ingot generated by the Czochralski process is pulled from growth zone 210. Growth zone 210 extends within inner wall 124 of inner crucible 120. Non-growth zone 220 further provides an area into which additional material is added to the melt.

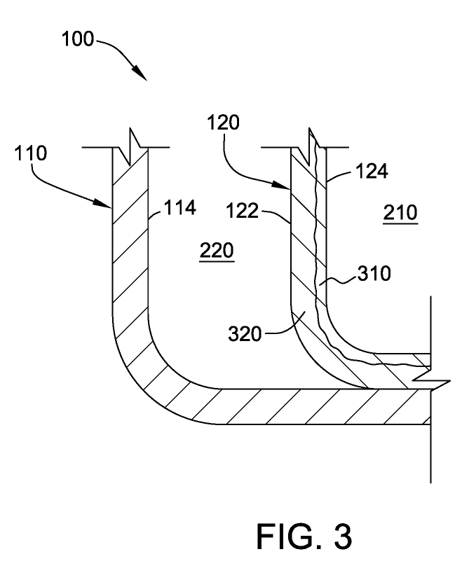

Referring now to FIG. 3, a detailed sectional view of the crucible assembly 100 shown in FIG. 1 is illustrated. Inner crucible 120 is formed by the arc-fusion process. The crucible wall includes two portions. A high purity portion 310 is made of high purity sand or synthetic quartz and forms inner wall 124 which defines growth zone 210. A lower purity portion 320 of the crucible wall is made of lower purity sand and forms outer wall 122 of the crucible. Outer wall 122 defines, in part, non-growth zone 220.

In operation, the melt contained within inner crucible 120 and outer crucible 110 gradually dissolves crucible walls 114, 122, and 124. This dissolution reaction introduces material from crucible walls 114, 122, and 124 into the melt. Material from inner wall 114 of outer crucible 110 introduces impurities into the melt. Substantially no impurities are introduced from inner wall 124 and outer wall 122 of inner arc-fused crucible 120. Impurities from outer crucible 110 enter non-growth zone 220 of crucible assembly 100.

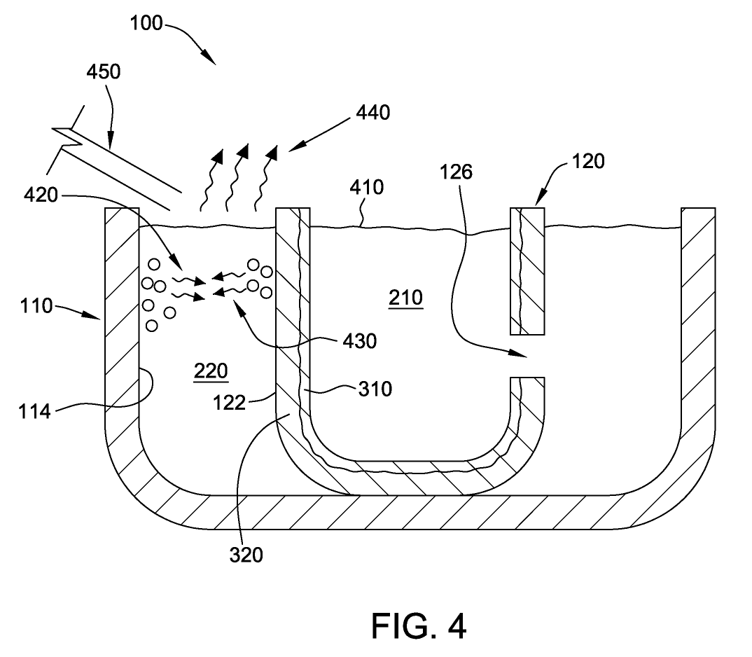

Referring now to FIG. 4, a sectional view of crucible assembly 100 shown in FIG. 1 including molten material contained within crucible assembly 100 is illustrated. Melt 410 includes impurities 420 introduced into melt 410 from inner wall 114 of outer crucible 110. Melt 410 further includes impurities 430 introduced into melt 410 from outer wall 122 and lower purity portion 320 of inner crucible 120. Impurities 420 and impurities 430 are separated from growth zone 210 by inner crucible 120. Impurities 420 and impurities 430 are substantially contained within non-growth zone 220. At least a portion of at least one high-partial-pressure species of impurities 420 and/or impurities 430 leave melt 410 through evaporation 440. This occurs before the high-partial-pressure species reach growth zone 210 and are thus reduced in concentration from the crystal ingot pulled from growth zone 210. For example, one high-partial-pressure species is lithium.

Melt 410 flows from non-growth zone 220 into growth zone 210 through channel 126. At least some impurities 420, 430 of melt 410 do not reach growth zone 210 because they evaporate 440 from non-growth zone 220 before melt 410 travels through channel 126. Impurities 420 from the cast outer crucible 110 evaporate 440 in non-growth zone 220 and are prevented from entering growth zone 210. Impurities 420 are therefore excluded from the crystal ingot pulled from growth zone 210. This allows for the use of cast crucibles as outer crucible 110 which typically have a higher impurity content, e.g., greater than 50 ppmw, such as between 200 ppmw and 500 ppmw. The high impurity content of cast crucibles can originate from ball milling media used to pulverize fused silica feedstock, impurity in the mold material used to create the cast crucible, and the binder and dispersing agent. Crucible assembly 100 generates a higher purity crystal ingot by preventing at least some impurities from entering growth zone 210 and by preventing those impurities from being incorporated into the crystal ingot. Crucible system 100 benefits from the increased design flexibility, reduced cost, and increased crucible lifetime afforded by cast outer crucible 110 while reducing the impact of some impurities in cast outer crucible 110.

Additional melt material (e.g., polysilicon) is added to melt 410 by feeder 450. Feeder 450 is positioned to add additional melt material to melt 410 in non-growth zone 220. This allows for crucible assembly 100 to be used in a continuous Czochralski process. Feeder 450 is also positioned opposite channel 126. This prevents solid material, e.g., polysilicon, from entering growth zone 210 before the material is melted. Additionally, impurities from additional melt material are prevented from entering growth zone 210 by inner crucible 120. These impurities may evaporate 440 from melt 410. Crucible assembly 100 therefore generates a higher purity crystal ingot by preventing at least some impurities from additional material, added to melt 410, from entering growth zone 210.

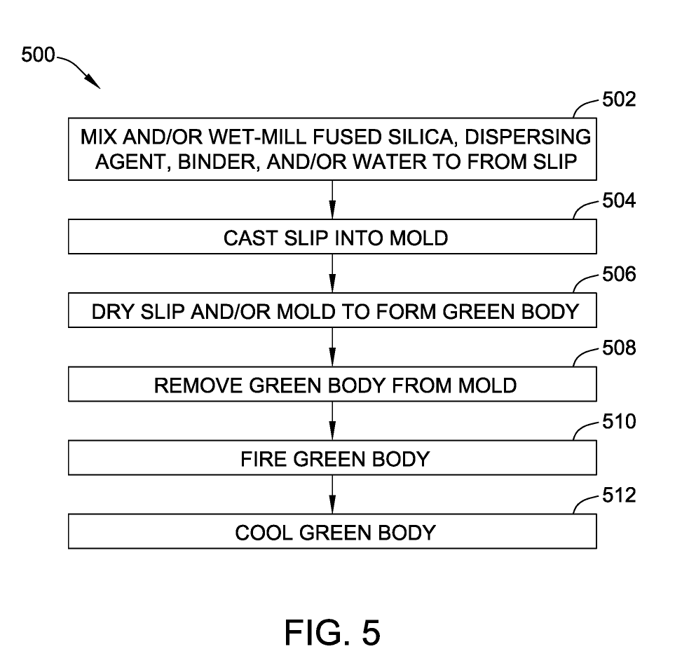

Referring now to FIG. 5, a flow chart illustrates an example method 500 for making, using a slip casting process, a crucible for use in the crucible assembly 100 shown in FIG. 1. This and/or other processes are used to make outer crucible 110. The method 500 generally includes mixing 502 silica and other components to form slip, casting 504 the slip into a mold, drying 506 the slip and/or mold to form a green body, removing 508 the green body from the mold, firing 510 the green body, and cooling 512 the green body.

The step of mixing 502 silica and other components to form slip includes mixing silica with dispersing agent, binder, and/or water to form slip. The silica which is mixed may be fused silica which is wet-milled. Casting 504 the slip into the mold includes pouring the slip mixture into the mold. The mold is typically made of plaster of Paris. In embodiments where gel casting is used rather than slip casting, the mold is, for example, stainless steel. The step of drying 506 the slip and/or mold to form the green body includes water moving out of the slurry through capillary action with or without assistance from vacuum drying. A green body is an unfired shaped powder form. During the drying of the slip, dried mass forms along the mold wall. When the desired thickness of the dried mass is reached, the remaining liquid slurry is poured out. Firing 510 the green body includes sintering or fusing the dried mass, e.g., the silica within the dried mass, at high temperature.

In an alternative embodiment, outer crucible 110 is made using a gel casting process or other casting process. In a gel casting process, ceramic powder, e.g., natural sand, synthetic quartz, or SiO₂, is milled and/or mixed with water, a dispersant, and gel-forming organic monomers. The mixture is placed under partial vacuum to remove air from the mixture. This increases the rate of drying and/or reduces the formation of bubbles in the gel cast product. A catalyst, e.g., a polymerization initiator, is added to the mixture. The polymerization initiator begins a gel-forming chemical reaction within the mixture. The slurry mixture is cast by pouring the mixture into a mold of the desired shape for creating the product, e.g., a crucible. The mold may be made of, for example, metal, glass, plastic, wax, or other materials. A gel is created from the slurry mixture by heating the molds and slurry mixture in a curing oven. The heat and catalyst cause the monomers in the mixture to form cross-linked polymers which trap water in the mixture to great a polymer-water gel. The gel binds and immobilizes the ceramic particles within the gel. The ceramic is removed from the mold. The ceramic is dried. The dried ceramic may be machined to further shape the ceramic. The ceramic is fired to burn out the polymer within the ceramic and sinter the ceramic particles. In further alternative embodiments, other casting, machining, or production processes are used to make outer crucible 110.

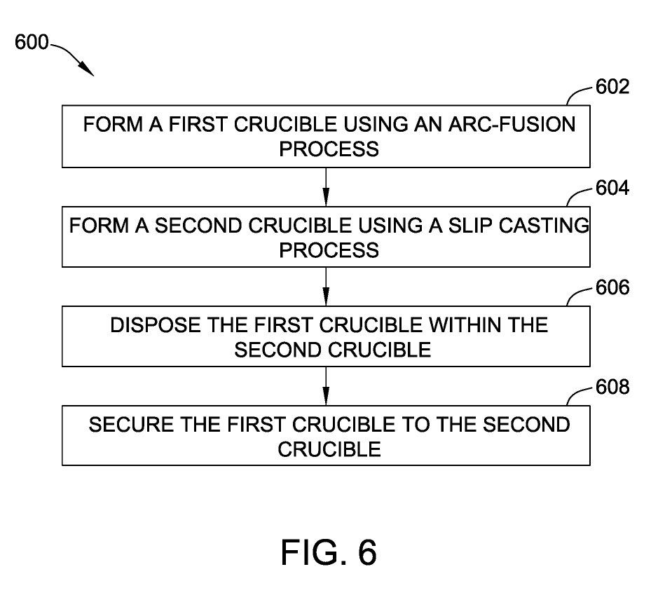

Referring now to FIG. 6, a flow chart illustrates method 600 for making the crucible assembly shown in FIG. 1. The method 600 generally includes forming 602 a first crucible using an arc-fusion process, forming 604 a second crucible using a slip casting process, disposing 606 the first crucible within the second crucible, and fixing or securing 608 the first crucible to the second crucible. The first crucible, formed using the arc-fusion process, is used as the inner crucible 120 in crucible assembly 100. Forming 604 the second crucible using the slip casting process includes forming the crucible according to method 500 illustrated in FIG. 5. The second crucible, formed using the slip casting process, is used as the outer crucible 110 in crucible assembly 100. In alternative embodiments, outer crucible 110 is formed using an alternative process such as gel casting.

Disposing 606 the first crucible within the second crucible may include centering the first crucible within the second crucible. Securing 608 the first crucible to the second crucible may include using silica nanoparticles to join the first crucible to the second crucible. In alternative embodiments, securing 608 the first crucible to the second crucible includes securing the first crucible within the second crucible using the geometry of the second crucible. For example, the second crucible may include a ridge, depression, and/or other feature which secures the first crucible.

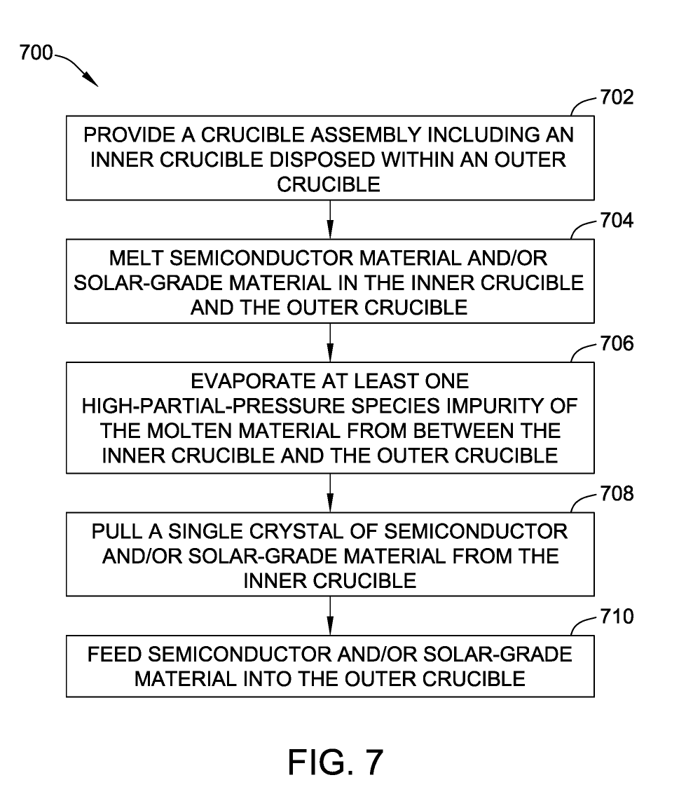

Referring now to FIG. 7, a flow chart illustrates a method 700 for pulling a crystal ingot using the Czochralski method and crucible assembly 100 shown in FIG. 1. Method 700 generally includes providing 702 a crucible assembly 100 including an inner crucible 120 and an outer crucible 110, melting 704 semiconductor material and/or solar grade material in the crucible assembly 100, evaporating 706 at least one high-partial-pressure impurity species from the melt, pulling 708 a single crystal of semiconductor and/or solar grade material from crucible assembly 100, and feeding 710 semiconductor and/or solar grade material into the crucible assembly 100 (e.g., into outer crucible 110).

The crucible assembly 100 provided for use in method 700 includes inner crucible 120 disposed within outer crucible 110 as shown in FIG. 1. Crucible assembly 100 further includes channel 126 configured to allow melt material to flow from outer crucible 110 into inner crucible 120. Melting 704 semiconductor material and/or solar grade material in crucible assembly 100 includes melting the material in both outer crucible 110 and inner crucible 120. For example, the material is heated in both outer crucible 110 and inner crucible 120. In alternative embodiments, the material is heated only in outer crucible 110 and flows through channel 126 into inner crucible 120. Following melting 704 of the material, molten material at least partially fills both outer crucible 110 and inner crucible 120. Evaporating 706 at least one high-partial-pressure impurity species from the melt includes evaporating impurities from the melt contained in non-growth zone 220 between outer crucible 110 and inner crucible 120. Pulling 708 a single crystal of semiconductor and/or solar grade material from crucible assembly 100 includes pulling 708 the single crystal from growth zone 210 within inner crucible 120. Feeding 710 semiconductor and/or solar grade material into the crucible assembly 100 includes adding additional material to outer crucible 110 in non-growth zone 220.

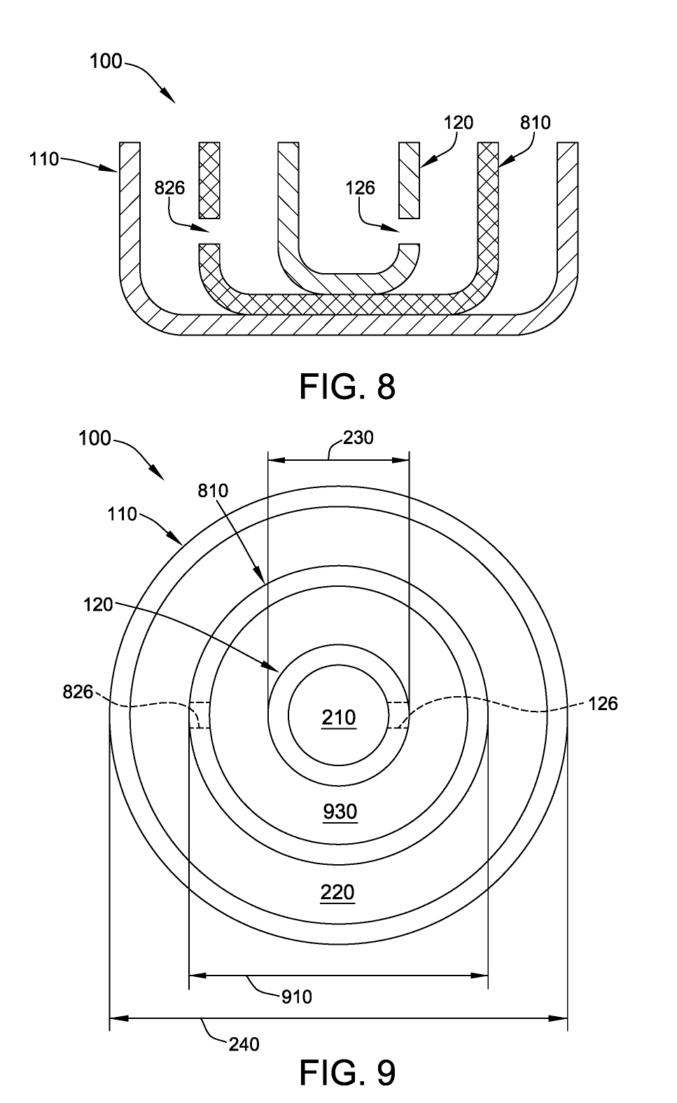

Referring now to FIG. 8, a sectional view of an alternative embodiment of crucible assembly 100 is illustrated. Crucible assembly 100 includes an inner crucible 120, an intermediate crucible 810, and an outer crucible 110. Crucible assembly 100 includes crucibles of at least two different types. In comparison to a crucible assembly having only a single type of crucible, this provides for a reduced total cost of crucible assembly 100, increased design flexibility, increased crucible lifespan.

Inner crucible 120 is an arc-fused crucible of the type described in crucible assembly 100 shown in FIG. 1. Intermediate crucible 810 is a slip cast crucible of the type described in crucible assembly 100 shown in FIG. 1. Outer crucible 110 is a slip cast crucible of the type described in crucible assembly 100 shown in FIG. 1. In alternative embodiments, intermediate crucible 810 and/or outer crucible 110 are formed by a process other than slip casting. For example, intermediate crucible 810 and/or outer crucible 110 are formed using a gel casting process. In further alternative embodiments, intermediate crucible 810 and/or outer crucible 110 are formed by a non-casting process such as an arc-fusion process. In some embodiments, for example, intermediate crucible 810 and/or outer crucible 110 is an arc-fused crucible.

Inner crucible 120, an arc-fused crucible, is disposed within intermediate crucible 810 and outer crucible 110. Inner crucible 120 is centered within intermediate crucible 810. Inner crucible 120 is fixed or secured to intermediate crucible 810 by bonding inner crucible 120 to intermediate crucible 810. For example, silica nanoparticles are used to bind inner crucible 120 to intermediate crucible 810. Inner crucible 120 includes a channel 126 of the type described in crucible assembly 100 shown in FIG. 1. Channel 126 is configured to allow melt material to flow between intermediate crucible 810 and inner crucible 120. In some embodiments, an interior and/or an exterior wall of inner crucible 120 is formed from ultra-high purity natural sand or synthetic quartz, whereas the rest of inner crucible 120 is formed of lower purity sand (e.g., high purity quartz).

Intermediate crucible 810, a slip cast crucible or other type of cast crucible, is disposed within outer crucible 110. Intermediate crucible 810 is centered within outer crucible 110. Intermediate crucible 810 is fixed or secured to outer crucible 110 by bonding intermediate crucible 810 to outer crucible 110. For example, silica nanoparticles are used to bind intermediate crucible 810 to outer crucible 110. Intermediate crucible 810 includes a channel 826 of the type described in crucible assembly 100 shown in FIG. 1. Channel 826 is configured to allow melt material to flow between intermediate crucible 810 and outer crucible 110.

Outer crucible 110 and intermediate crucible 810 are both formed using the slip casting process, or another type of casting process, to provide greater design flexibility over that of arc-fused crucibles and results in much cheaper crucibles in comparison to if arc-fused crucibles are used. The slip casting process, or other type of casting process, provides for less costly design changes to intermediate crucible 810 and outer crucible 110 in comparison to the arc-fusion process. The size and or shape of outer crucible 110 and/or intermediate crucible 810 may be changed using the slip casting process or another casting process with reduced capital expenditure compared to arc-fusion. This is a result of the flexibility and lower cost of the slip cast, or other casting, mold and slurry in comparison to the equipment used in the arc-fusion process. As the size of the crucible made by the arc-fusion process increases, the cost likewise increases. Therefore, using a slip cast, or otherwise cast, crucible as outer crucible 110 and intermediate crucible 810 in crucible assembly 100 reduces cost while providing increased flexibility of the size and geometry of outer crucible 110 and intermediate crucible 810.

In alternative embodiments, one or both of intermediate crucible 810 and outer crucible 110 is an arc-fused crucible. Additionally or alternatively, in some embodiments, the interior and/or exterior walls of intermediate crucible 810 and outer crucible 110 are formed from ultra-high purity natural sand or synthetic quartz.

Referring now to FIG. 9, a plan view of the crucible assembly 100 shown in FIG. 8 is illustrated. Outer crucible 110, intermediate crucible 810, and inner crucible 120 are circular. Inner crucible 120 is nested within intermediate crucible 810, and intermediate crucible 810 is nested within outer crucible 110. For example, inner crucible 120 is centered within intermediate crucible 810, and intermediate crucible 810 is centered within outer crucible 110. Outer crucible 110 has a larger diameter 240 than the diameter 910 of intermediate crucible 810. Intermediate crucible 810 has a larger diameter 910 than diameter 230 of inner crucible 120. In some embodiments, outer crucible 110 has an outer diameter 240 of at least twenty inches, less than forty inches, between twenty four inches and thirty six inches, between twenty eight inches and thirty eight inches, or between thirty inches and forty inches. In some embodiments, intermediate crucible has an outer diameter 910 of at least twenty inches, less than forty inches, between twenty four inches and thirty two inches, between twenty eight inches and thirty four inches, or between thirty inches and thirty six inches. In some embodiments, inner crucible 120 has an outer diameter 230 of at least eighteen inches, less than thirty inches, between eighteen inches and twenty two inches, between twenty inches and twenty four inches, between twenty two inches and twenty six inches, between twenty four inches and twenty eight inches, or between twenty six inches and thirty inches.

In alternative embodiments, inner crucible 120, intermediate crucible 810, and/or outer crucible 110 have other configurations. For example, inner crucible 120, intermediate crucible 810, and/or outer crucible 110 may have different shapes such as, but not limited to, square or rectangular. Inner crucible 120, intermediate crucible 810, and/or outer crucible 110 may have different diameters in some embodiments. For example, inner crucible 120 may have a diameter 230 of eighteen inches or less, greater than thirty inches, or an intermediate value. Intermediate crucible 810 may have a diameter 910 less than twenty inches, greater than forty inches, or an intermediate value. Outer crucible 110 may have a diameter 240 less than twenty inches, greater than forty inches, or an intermediate value.

Outer crucible 110 and intermediate crucible 810 define a non-growth zone 220. Non-growth zone 220 extends between outer crucible 110 and intermediate crucible 810. Non-growth zone 220 provides an area from which impurities are removed from the melt through evaporation. Non-growth zone 220 further provides an area into which additional material is added to the melt. Intermediate crucible 810 and inner crucible 120 define an intermediate non-growth zone 930. Intermediate non-growth zone 930 extends between intermediate crucible 810 and inner crucible 120. Intermediate non-growth zone 930 provides an area from which impurities are removed from the melt through evaporation. Non-growth zone 220 and intermediate non-growth zone 930 function the same as non-growth zone 220 described with reference to FIGS. 2-4. Inner crucible 120 defines growth zone 210. The crystal ingot grown using the Czochralski process is pulled from growth zone 210. Growth zone 210 functions as growth zone 210 described in reference to FIGS. 2-4.

Crucible assembly 100 including arc-fused inner crucible 120 and slip cast, or otherwise cast, outer crucible 110 results in reduced cost, improved design flexibility, improved crucible lifetime, and limited impurities being introduced into a single crystal ingot drawn from crucible assembly 100. Crucible assembly 100 reduces cost through the use of slip cast outer crucible 110. The reduced cost of slip casting in comparison to arc-fusion, and its use for the larger outer crucible 110, results in a reduced cost. The cost of producing cast crucibles is less than producing arc-fused crucibles because the capital equipment used in producing cast crucibles is less expensive than that of arc-fused crucibles. Crucible assembly 100 has improved design flexibility resulting from the inclusion of cast outer crucible 110. Molds used to produce cast crucibles can be more easily and more cheaply altered to produce different crucible geometries, e.g., larger or smaller diameter crucibles, in comparison to the equipment used to produce arc-fused crucibles, e.g., rotating molds, electrodes, etc. Crucible system 100 has improved crucible lifetime as a result of cast outer crucible 110. Cast outer crucible 110 has a lower dissolution rate than arc-fused crucibles. This increases the lifetime of outer crucible 110. Although cast outer crucible 110 includes more impurities than an arc-fused crucible, the geometry of crucible system 100 limits impurities from being introduced into a single crystal ingot drawn from crucible system 100. At least some impurities from outer crucible 110 evaporate from the melt in outer crucible 110 before they enter inner crucible 120 from which the single crystal ingot is pulled.

When introducing elements of the present invention or the embodiment(s) thereof, the articles “a”, “an”, “the” and “said” are intended to mean that there are one or more of the elements. The terms “comprising”, “including” and “having” are intended to be inclusive and mean that there may be additional elements other than the listed elements. The use of terms indicating a particular orientation (e.g., “top”, “bottom”, “side”, “down”, “up”, etc.) is for convenience of description and does not require any particular orientation of the item described.

As various changes could be made in the above constructions and methods without departing from the scope of the invention, it is intended that all matter contained in the above description and shown in the accompanying drawing[s] shall be interpreted as illustrative and not in a limiting sense.

1. A crucible assembly for growing a crystal ingot using a Czochralski process, the assembly comprising:
an outer crucible; and
an inner crucible, the inner crucible disposed within the outer crucible, the inner crucible having a channel configured for fluid communication between the outer crucible and the inner crucible, wherein the inner crucible is an arc-fused crucible and the outer crucible is a cast crucible.

2. The crucible assembly of claim 1, wherein the inner crucible is bonded to the outer crucible.

3. The crucible assembly of claim 1, wherein the outer crucible has a dissolution rate less than a dissolution rate of the inner crucible.

4. The crucible assembly of claim 1, wherein the inner crucible is formed from higher purity quartz sand than the outer crucible.

5. The crucible assembly of claim 1, wherein the outer crucible comprises a silica wall.

6. The crucible assembly of claim 1, wherein the inner crucible includes:
an interior wall portion of at least one of ultra-high purity natural sand or synthetic quartz; and
an outer wall portion of lower purity sand or quartz than the interior wall portion, the outer wall portion fused to the interior wall portion.

7. The crucible assembly of claim 6, wherein the inner crucible defines a growth zone from which a crystal ingot is pulled during the Czochralski process, wherein the outer crucible and the inner crucible define a non-growth zone between the outer crucible and the inner crucible, and wherein the non-growth zone is configured to separate impurities from the growth zone that are introduced into a melt from the outer wall portion.

8. The crucible assembly of claim 1, wherein the inner crucible defines a growth zone from which a crystal ingot is pulled during the Czochralski process, wherein the outer crucible and the inner crucible define a non-growth zone between the outer crucible and the inner crucible, and wherein the non-growth zone is configured to allow for high-partial-pressure species to evaporate from a melt during the Czochralski process.

9. The crucible assembly of claim 1, wherein the outer crucible is a slip cast crucible.

10. The crucible assembly of claim 1, wherein the outer crucible is a gel cast crucible.

11. The crucible assembly of claim 1 further comprising an intermediate crucible disposed between the outer crucible and the inner crucible.

12. The crucible assembly of claim 11, wherein the intermediate crucible is an opaque cast crucible.

13. The crucible assembly of claim 11, wherein the intermediate crucible is a transparent arc-fused crucible.

14. A method of growing a single crystal ingot by a Czochralski process, the method comprising:
melting semiconductor or solar-grade material in a crucible assembly to form a melt, the crucible assembly including an inner, arc-fused crucible disposed within an outer, cast crucible; and
pulling a single crystal of semiconductor or solar-grade material from the melt within the inner crucible.

15. The method of claim 14 further comprising evaporating at least one high-partial-pressure impurity species from the melt between the inner crucible and the outer crucible, wherein the at least one high-partial-pressure impurity is introduced into the melt through dissolution of the outer crucible.

16. The method of claim 14 further comprising feeding semiconductor material or solar-grade material into the outer crucible.

17-21. (canceled)

22. A method of assembling a crucible assembly, the method comprising:
providing an arc-fused crucible;
providing a cast crucible, wherein the cast crucible has a larger diameter than the arc-fused crucible;
positioning the arc-fused crucible within the cast crucible; and
fixing the arc-fused crucible to the cast crucible.

23. The method of claim 22, wherein fixing the arc-fused crucible to the cast crucible includes fusing the arc-fused crucible to the cast crucible using silica nanoparticles.

24. The method of claim 22 further comprising:
providing an intermediate crucible;
positioning the intermediate crucible within the cast crucible; and
positioning the arc-fused crucible within the intermediate crucible.

25. The method of claim 24, wherein the intermediate crucible is a cast crucible.

26. The method of claim 24, wherein the intermediate crucible is an arc-fused crucible.
